(19) United States
(12) Patent Application Publication
(10) Pub. No.: US 2022/0209084 A1
(43) Pub. Date: Jun. 30, 2022

(54) LED MODULE AND DISPLAY DEVICE HAVING LED MODULE

(71) Applicant: Japan Display Inc., Tokyo (JP)

(72) Inventors: Kenichi TAKEMASA, Tokyo (JP); Kazuyuki YAMADA, Tokyo (JP); Keisuke ASADA, Tokyo (JP); Daiki ISONO, Tokyo (JP)

(73) Assignee: Japan Display Inc., Tokyo (JP)

(21) Appl. No.: 17/551,182

(22) Filed: Dec. 15, 2021

(30) Foreign Application Priority Data
Dec. 25, 2020 (JP) 2020-216923

(51) Int. Cl. H01L 33/62; H01L 25/075; H01L 33/38

(52) U.S. Cl. CPC H01L 33/62; H01L 33/38; H01L 25/0753

(57) ABSTRACT

An LED module includes a first electrode, a second electrode arranged isolated from the first electrode, a first bump on the first electrode, a second bump on the second electrode, a protrusion between the first electrode and the second electrode, and an LED chip having a first pad electrode and a second pad electrode. The protrusion has insulating properties, the first pad electrode of the LED chip is disposed opposite the first electrode, the second pad electrode is disposed opposite the second electrode, the first pad electrode is connected to the first electrode through the first bump, and the second pad electrode is connected to the second electrode through the second bump.

### CROSS-REFERENCE TO RELATED APPLICATION

This application is based upon and claims the benefit of priority from the prior Japanese Patent Application No. 2020-216923, filed on Dec. 25, 2020, the entire contents of which are incorporated herein by reference.

### FIELD

An embodiment of the present invention relates to an LED module in which a light emitting diode (LED) is mounted in a bare chip state. An embodiment of the present invention relates to a pixel structure of a display device in which pixels are formed by light emitting diodes.

### BACKGROUND

A micro LED display is known in which a microscopic light emitting diode called a micro LED is mounted on pixels arranged in a matrix. The micro LED displays are common to organic EL displays using organic electroluminescent devices in that pixels are self-light emitting. While the organic EL displays directly form organic electroluminescent elements on substrates called backplanes on which thin film transistors (TFTs) are fabricated, the micro LED displays differ in that LED chips fabricated on sapphire substrates and the like are mounted on backplanes.

The micro LED display is mounted on a backplane with micro LEDs face down. A flowable conductive paste or solder is used to mount the micro LEDs. In this case, it is necessary to precisely control the application position and the application amount of the conductive paste or solder. However, it is necessary to take care of short-circuits between electrodes due to the small chip size of micro LEDs.

### SUMMARY

An LED module in an embodiment according to the present invention includes a first electrode, a second electrode arranged isolated from the first electrode, a first bump on the first electrode, a second bump on the second electrode, a protrusion between the first electrode and the second electrode, and an LED chip having a first pad electrode and a second pad electrode. The protrusion has insulating properties, the first pad electrode of the LED chip is disposed opposite the first electrode, the second pad electrode is disposed opposite the second electrode, the first pad electrode is connected to the first electrode through the first bump, and the second pad electrode is connected to the second electrode through the second bump.

A display device in an embodiment according to the present invention includes a first electrode arranged in a region where pixels are formed, a second electrode arranged isolated from the first electrode, a first bump on the first electrode, a second bump on the second electrode, a protrusion arranged between the first electrode and the second electrode, and an LED chip having a first pad electrode and a second pad electrode. The protrusion has insulating properties, the first pad electrode of the LED chip is disposed opposite the first electrode, the second pad electrode is disposed opposite the second electrode, the first pad electrode is connected to the first electrode through the first bump, and the second pad electrode is connected to the second electrode through the second bump.

### BRIEF DESCRIPTION OF DRAWINGS

FIG. 1A shows a plan view of an LED module according to an embodiment of the present invention;

FIG. 1B shows a cross-sectional view of an LED module according to an embodiment of the present invention;

FIG. 2 shows a perspective view illustrating the structure of an LED chip;

FIG. 3A shows a cross-sectional view of an LED module according to an embodiment of the present invention;

FIG. 3B shows a cross-sectional view of an LED module according to an embodiment of the present invention;

FIG. 4 shows a cross-sectional structure of an LED module according to an embodiment of the present invention;

FIG. 5A shows a cross-sectional view of an LED module according to an embodiment of the present invention;

FIG. 5B shows a cross-sectional view of an LED module according to an embodiment of the present invention;

FIG. 6 shows a configuration of a display device according to an embodiment of the present invention; and

FIG. 7 is a cross-sectional view of a pixel in a display device according to an embodiment of the present invention.

### DESCRIPTION OF EMBODIMENTS

Hereinafter, embodiments of the present invention will be described with reference to the drawings and the like. The present invention may be carried out in various forms without departing from the gist of the invention thereof, and is not to be construed as being limited to any of the following embodiments. Although the drawings may schematically represent the width, thickness, shape, and the like of each part in comparison with the actual embodiment in order to clarify the description, they are merely examples and do not limit the interpretation of the present invention. In the present specification and each of the figures, elements similar to those described previously with respect to the figures already mentioned are designated by the same reference numerals (or numbers followed by a, b, etc.), and a detailed description thereof may be omitted as appropriate. Furthermore, the characters “first” and “second” appended to each element are convenient signs used to distinguish each element, and have no further meaning unless specifically described.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions. In the following description, unless otherwise specified, it is assumed that the LED chips are “on” or “above the substrate when the substrate is used as a reference and that the substrate is “under” or “below” the LED chips when the LED chips are used as a reference.

The micro LED in the present invention refers to an LED having a chip size of several micrometers or more and 100 micrometers or less, and the mini LED refers to an LED having a chip size of 100 micrometers or more. An embodiment of the present invention can use LEDs of any size and can be used depending on the pixel size of the LED module and the display device.

### First Embodiment

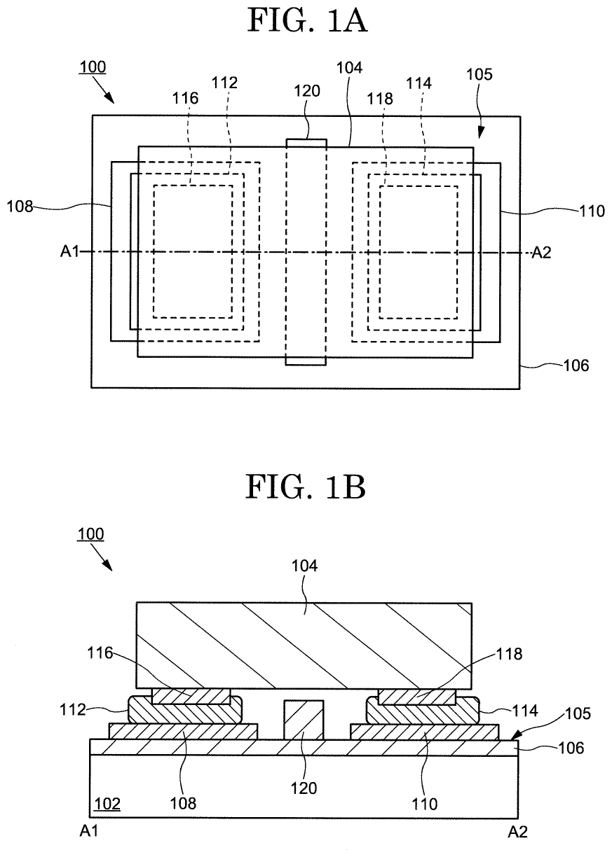

FIG. 1A and FIG. 1B illustrate the configuration of an LED module 100 according to one embodiment of the present invention. FIG. 1A shows a plan view of the LED module 100 and FIG. 1B shows a cross-sectional view corresponding to the lines A1-A2.

The LED module 100 has a structure in which an LED chip 104 is mounted on a first electrode 108 and a second electrode 110 which are arranged on an insulating surface 105. The insulating surface 105 is formed of an insulating substrate. The insulating surface 105 may also be formed by a first insulating layer 106 disposed on a substrate 102. Although not shown in FIG. 1A and FIG. 1B, wrings may be arranged on the substrate to be connected to the LED chip 104 and a drive circuit may be arranged to control the light emission of the LED chip 104.

The first electrode 108 and the second electrode 110 are spaced apart on the insulating surface 105. In other words, the first electrode 108 and the second electrode 110 are electrically isolated from each other. The first electrode 108 and the second electrode 110 are arranged to match the spacing of a pair of electrodes (first pad electrode 116, second pad electrode 118) arranged with the LED chip 104, as will be described below.

Although not limited to the material forming the first electrode 108 and the second electrode 110, a conductive material having fluidity during coating or dropping and a material having good wettability are selected. The first electrode 108 and the second electrode 110 are formed of a conductive material such as, for example, gold (Au), copper (Cu), silver (Ag), tin (Sn), and aluminum (Al). The first electrode 108 and the second electrode 110 are formed of a thickness of 0.5 μm to 2 μm, 0.8 μm to 1.5 μm. Although the distance between the first electrode 108 and the second electrode 110 is arbitrary, when the LED chip 104 is a micro LED, the distance is 10 μm or less.

The LED chip 104 is a two-terminal device having a first pad electrode 116 and a second pad electrode 118 for so-called flip-chip mounting. For example, the LED chip 104 is mounted on the substrate 102, and the first pad electrode 116 and the second pad electrode 118 are arranged on the surface facing the first electrode 108 and the second electrode 110. One of the first pad electrode 116 and the second pad electrode 118 is connected to a p-type semiconductor layer while the other is connected to an n-type semiconductor layer. From such a connection structure, one of the first pad electrode 116 and the second pad electrode 118 is referred to as the p electrode and the other as the n electrode. Preferably, the first pad electrode 116 and the second pad electrode 118 are formed of a metal material to improve wettability with a flowable conductive material and have a metal surface such as gold (Au) or silver (Ag) to improve wettability with the flowable conductive material. This type of first pad electrode 116 and second pad electrode 118 are formed of a thickness of about 1 μm to 5 μm.

The LED chip 104 is mounted on the substrate 102 using a first bump 112 and a second bump 114. The first pad electrode 116 and the first electrode 108 are electrically connected by the first bump 112 and the second pad electrode 118 and the second electrode 110 are electrically connected by the second bump 114.

The first bump 112 and the second bump 114 are formed of a conductive material having fluidity in their initial state (prior to curing). For example, a conductive paste is used as the first bump 112 and the second bump 114. A silver paste, a carbon paste, or a paste having silver and carbon mixed therewith is used as the conductive paste. Tin may also be used as the solder paste for the first bump 112 and the second bump 114. For example, tin bumps may be used as the first bump 112 and the second bump 114. The first bump 112 and the second bump 114 have a height of about 1 μm to 10 μm in a state where they are dropped onto the first electrode 108 and the second electrode 110.

The conductive paste has fluidity, and is hardened by baking or simply drying after dropping onto an object. To form the first bump 112 and the second bump 114 by using a conductive paste, it is necessary to precisely control the position and the dropping amount to each of the first electrode 108 and the second electrode 110. When too much conductive paste is dropped, widening and shorting between the electrodes occurs. On the other hand, if the amount of conductive paste which is dropped is too small, the electrical continuity will be defective, and the force (adhesive force) that fixes the LED chip 104 will decrease, resulting in a problem of peeling.

In addition, after the conductive paste or solder paste is dropped onto the first electrode 108 and the second electrode 110, when the LED chip 104 is placed on the first electrode 108 and the second electrode 110 and pressed, there is a phenomenon in which the conductive paste spreads laterally. Excessive pressing force on the LED chip 104 increases the spread of the conductive paste and causes adjacent conductive paste to come into contact with each other. Further, when the amount conductive paste or the solder paste which is dropped is too large, the spread of the conductive paste or the solder paste becomes large, and the first electrode 108 and the second electrode 110 are short-circuited. When conductive paste or solder paste is used to form the first bump 112 and the second bump 114, precise control of the dropping amount is required. However, since the LED chip 104 has a small size, it is difficult to precisely control the dropping amount of the conductive paste and the solder paste.

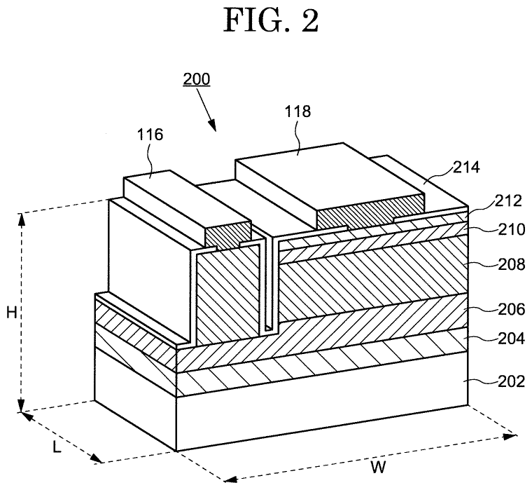

FIG. 2 illustrates an example of an LED chip 200. The LED chip 200 has a substrate 202 formed of a semiconductor wafer such as GaAs or an insulating material such as sapphire, a buffer layer 204 formed of gallium nitride or the like on the substrate 202, an n-type layer 206 formed of a gallium nitride-based compound semiconductor, an active layer 208 formed of a gallium nitride-based compound semiconductor having a quantum well structure, a p-type layer 210 formed of a gallium nitride-based compound semiconductor, a passivation layer 214, a first pad electrode 116, and a second pad electrode 118. The size of the LED chip 200 is referred to as a so-called micro LED having a length L of 10 μm to 20 μm, a width W of 20 μm to 40 μm, and a height H of about 150 μm. Therefore, the distance between the first pad electrode 116 and the second pad electrode 118 is 10 μm or less. However, the size of the LED chip 200 is not limited to a micro LED, and may be referred to as a so-called mini LED.

For such microstructures, the LED module 100 according to the present embodiment has a structure in which a protrusion 120 is arranged between the first electrode 108 and the second electrode 110 that forms a contact with the LED chip 104. The protrusion 120 is disposed on the insulating surface 105 so as to cross areas where the first electrode 108 and the second electrode 110 are isolated. The protrusion 120 has insulating properties has a height (thickness) at which an upper end is arranged higher than an upper surface of the first electrode 108 and the second electrode 110. This type of protrusion 120 is formed of an insulating material. The protrusion 120 also may have a configuration in which the surface of the conductive material is covered with an insulating film.

The protrusion 120 is formed using, for example, an insulating film such as silicon oxide (SiO₂) or aluminum oxide (Al₂O₃). The protrusion 120 may also be formed of organic insulating materials such as acrylics or epoxies, and the like.

The presence of the protrusion 120 prevents one or both of the first bump 112 and the second bump 114 from flowing and short-circuiting the first electrode 108 and the second electrode 110 when the first bump 112 and the second bump 114 are provided on the first electrode 108 and the second electrode 110 and the LED chip 104 is mounted. In other words, when the LED chip 104 is mounted on the substrate 102, even if the first bump 112 and the second bump flow laterally due to pressing, it is possible to prevent the bumps from coming into contact with each other by inhibiting the flow of the first bump 112 and the second bump 114 by the protrusion 120.

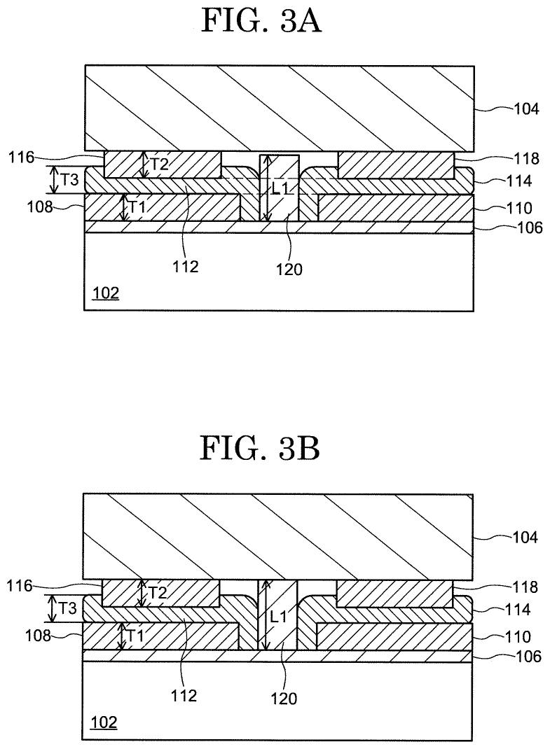

As shown in FIG. 3A, when a thickness of the first electrode 108 is T1 (the second electrode 110 is the same), a thickness of the first pad electrode 116 is T2 (the second pad electrode 118 is the same), the thickness of the first bump 112 is T3 (the second bump 114 is the same), and a height of the protrusion 120 is L1, the height L1 of the protrusion is preferably greater than the thickness T1 of the first electrode 108. In other words, the first electrode 108 has the thickness of T1, and the height L1 of the protrusion 120 is preferably greater than a height corresponding to the thickness T1 (L1>T1). Such relationships allow the top end of the protrusion 120 to protrude from the top surface of the first electrode 108 and the second electrode 110. The upper end of the protrusion 120 can be positioned in the area between the first pad electrode 116 and the second pad electrode 118, and short circuits can be prevented even when the first bump 112 and the second bump 114 are flowing, as shown is the diagram.

Preferably, the height L1 of the protrusion 120 is greater than the sum of the thickness T1 of the first electrode 108 and the thickness T2 of the first pad electrode 116 and is not in contact with the LED chip 104. Also, the height L1 of the protrusion 120 is preferably higher than the height corresponding to the thickness T1 of the first electrode 108, and lower than the height corresponding to the sum of the thickness T1 of the first electrode 108, the thickness T2 of the first pad electrode 116, and the thickness T3 of the first bump 112. The height L1 of the protrusion 120 prevents interference with the LED chip 104 and allows the LED chip 104 to be electrically connected to the first electrode 108 and the second electrode 110 securely by the first bump 112 and the second bump 114, by satisfying such relationships. Further, since the protrusion 120 has the height L1, it is possible to suppress misalignment when the LED chip 104 is mounted. Even if some positional misalignment occurs when mounting the first bump 112 and the first electrode 108, and the second bump 114 and the second electrode 110, the protrusion 120 serves as a stopper for the first bump 108 and the second bump 114, and excessive positional misalignment can be suppressed, thereby preventing a defect when mounting the LED chip 104.

Alternatively, as shown in FIG. 3B, the height L1 of the protrusion 120 may have a height at which the upper end contacts the LED chip 104. Since the protrusion 120 has such a height, short circuits between the first bump 112 and the second bump 114 are prevented, and the protrusion 120 can be used as a spacer for keeping a constant distance between the LED chip 104 and the substrate 102.

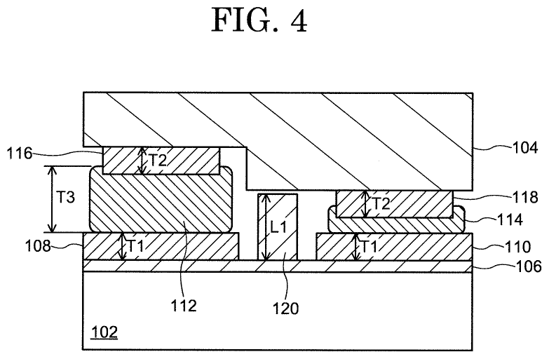

As shown in FIG. 4, even when the height of the first pad electrode 116 and the second pad electrode 118 in the LED chip 104 is different (when the distance D1 between the first pad electrode 116 and the first electrode 108 is greater than the distance D2 between the second pad electrode 118 and the second electrode 110), the height of the protrusion 120 is higher than the upper surface of the first electrode 108 and the second electrode 110, as described above, thereby preventing the first bump 112 and the second bump 114 from flowing and contacting.

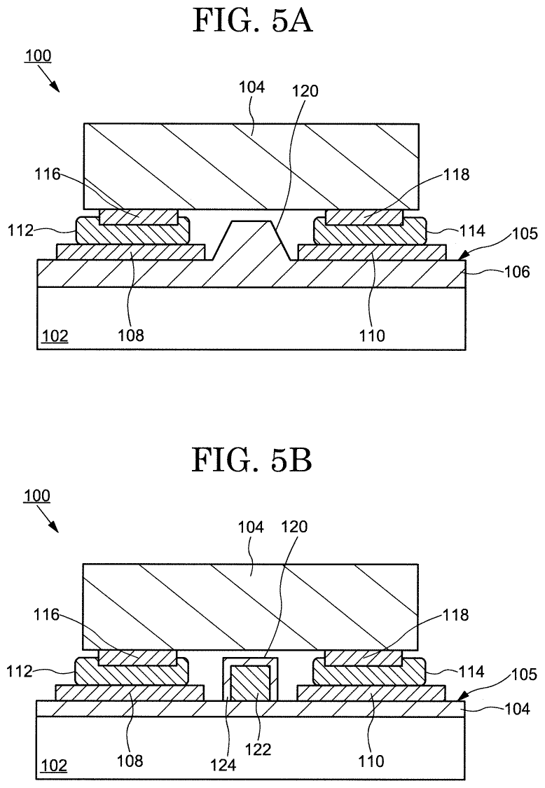

Similar to the configuration shown in FIG. 1B, the protrusion 120 may be formed by providing another insulating layer over the first insulating layer 106. The protrusion 120 may also be formed by selectively etching regions that form the first electrode 108 and the second electrode 110 in the first insulating layer 106, as shown in FIG. 5A. Further, as shown in FIG. 5B, a conductive layer 122 may be formed on the first insulating layer 106 and an insulating film 124 may be formed to cover the conductive layer 122.

### Second Embodiment

This embodiment illustrates a display device having an LED module configuration as shown in the first embodiment.

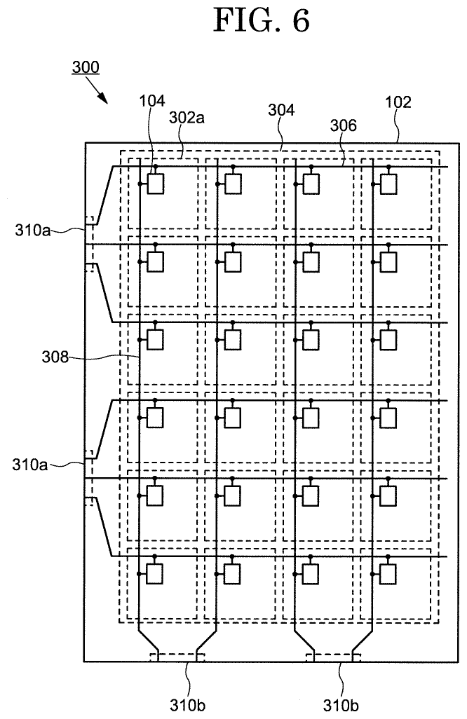

FIG. 6 shows a configuration of a display device 300 according to the present embodiment. The display device 300 includes a display part 304 on the substrate 102 in which pixels 302a are arranged in a matrix. The display part 304 is provided with a scanning signal line 306 for inputting a scan signal and a data signal line 308 for inputting an image signal into the pixels 302a. The scanning signal line 306 and the data signal line 308 are arranged to intersect. The peripheral portion of the substrate 102 is provided with an input terminal 310a of the scanning signal line 306 and an input terminal 310b of the data signal line 308. Although not illustrated in FIG. 9, a driver IC for driving the pixel 302a may be mounted on the substrate 102.

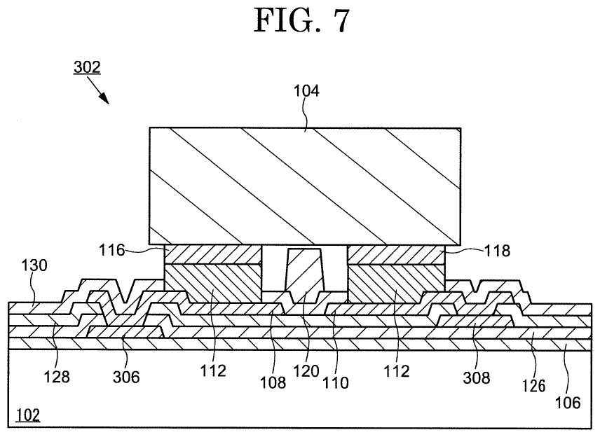

FIG. 7 shows an example of a cross-sectional structure of pixel 302a. The pixel 302a has a structure in which the first insulating layer 106, a second insulating layer 126, and a third insulating layer 128 are laminated from the side of the substrate 102 and the protrusion 120 is arranged on the insulating surface formed by the third insulating layer 128. The scanning signal line 306 is arranged between the first insulating layer 106 and the second insulating layer 126, and the data signal line 308 is arranged between the second insulating layer 126 and the third insulating layer 128. The display part 304 is arranged with the second insulating layer 126 between the scanning signal line 306 and the data signal line 308 to allow the two signal lines to intersect.

The first electrode 108 is arranged to overlap with a contact hole which passes through the third insulating layer 128 and the second insulating layer 126 and is connected to the scanning signal line 306. The second electrode 110 is arranged to overlap a contact hole which passes through the third insulating layer 128 and is connected to the data signal line 308. A passivation layer 130 may be further arranged on the top layer of the first electrode 108 and the second electrode 110.

The LED chip 104 is connected by the first pad electrode 116 to the first electrode 108 via the first bump 112 and the second pad electrode 118 to the second electrode 110 via the second bump 114. The provision of the protrusion 120 between the first electrode 108 and the second electrode 110 prevents short circuits between the electrodes of the LED chip 104 even when the first bump 112 and the second bump 114 are flowing. In other words, the protrusion 120 in the pixel 302 can provide a margin in the process of forming the first bump 112 and the second bump 114, thereby improving the productivity and the yield of the display device 300.

While the present embodiment illustrates an example in which a passive matrix type pixel is configured by an LED module, the present embodiment is not limited thereto, and may also be applied to an active matrix type pixel in which the light emission of the individual pixels is controlled by pixel circuit by a transistor.

What is claimed is:

1. An LED module, comprising:
a first electrode;
a second electrode arranged isolated from the first electrode;
a first bump on the first electrode;
a second bump on the second electrode;
a protrusion between the first electrode and the second electrode; and
an LED chip having a first pad electrode and a second pad electrode, wherein
the protrusion has insulating properties,
the first pad electrode of the LED chip is disposed opposite the first electrode, the second pad electrode is disposed opposite the second electrode, the first pad electrode is connected to the first electrode through the first bump, and the second pad electrode is connected to the second electrode through the second bump.

2. The LED module according to claim 1, wherein an upper end of the protrusion projects from an upper surface of the first electrode and the second electrode.

3. The LED module according to claim 1, wherein an upper end of the protrusion is located between the first pad electrode and the second pad electrode.

4. The LED module according to claim 1, wherein an upper end of the protrusion projects from an upper surface of the first electrode and the second electrode and is not in contact with the LED chip.

5. The LED module according to claim 1, wherein an upper end of the protrusion protrudes from an upper surface of the first electrode and the second electrode and is in contact with the LED chip.

6. The LED module according to claim 1, wherein the first electrode and the second electrode have a first thickness, and a height of the protrusion is higher than a height corresponding to the first thickness.

7. The LED module according to claim 1, wherein the first electrode and the second electrode have a first thickness, and the first pad electrode and the second pad electrode have a second thickness, and
a height of the protrusion is higher than a height corresponding to the first thickness and higher than a height corresponding to a total thickness of the first thickness and the second thickness.

8. The LED module according to claim 1, wherein the first electrode and the second electrode have a first thickness, and the first pad electrode and the second pad electrode have a second thickness,
the first bump has a third thickness in a position sandwiched between the first electrode and the first pad electrode, and
a height of the protrusion is higher than a height corresponding to the first thickness and lower than a height corresponding to a total thickness of the first thickness, the second thickness and the third thickness.

9. The LED module according to claim 1, wherein the protrusion is arranged across an area where the first electrode and the second electrode are isolated.

10. The LED module according to claim 1, wherein the first bump and the second bump are insulated from each other by the protrusion.

11. A display device, comprising:
a first electrode arranged in a region where pixels are formed;
a second electrode arranged isolated from the first electrode;
a first bump on the first electrode;
a second bump on the second electrode;
a protrusion arranged between the first electrode and the second electrode; and
an LED chip having a first pad electrode and a second pad electrode, wherein
the protrusion has insulating properties,
the first pad electrode of the LED chip is disposed opposite the first electrode, the second pad electrode is disposed opposite the second electrode, the first pad electrode is connected to the first electrode through the first bump, and the second pad electrode is connected to the second electrode through the second bump.

12. The display device according to claim 11, wherein an upper end of the protrusion projects from an upper surface of the first electrode and the second electrode.

13. The display device according to claim 11, wherein an upper end of the protrusion is located between the first pad electrode and the second pad electrode.

14. The display device according to claim 11, wherein an upper end of the protrusion projects from an upper surface of the first electrode and the second electrode and is not in contact with the LED chip.

15. The display device according to claim 11, wherein an upper end of the protrusion protrudes from an upper surface of the first electrode and the second electrode and is in contact with the LED chip.

16. The display device according to claim 11, wherein the first electrode and the second electrode have a first thickness, and a height of the protrusion is higher than a height corresponding to the first thickness.

17. The display device according to claim 11, wherein the first electrode and the second electrode have a first thickness, and the first pad electrode and the second pad electrode have a second thickness, and
a height of the protrusion is higher than a height corresponding to the first thickness and higher than a height corresponding to a total thickness of the first thickness and the second thickness.

18. The display device according to claim 11, wherein the first electrode and the second electrode have a first thickness, and the first pad electrode and the second pad electrode have a second thickness,
the first bump has a third thickness in a position sandwiched between the first electrode and the first pad electrode, and
a height of the protrusion is higher than a height corresponding to the first thickness and lower than a height corresponding to a total thickness of the first thickness, the second thickness and the third thickness.

19. The display device according to claim 11, wherein the protrusion is arranged across an area where the first electrode and the second electrode are isolated.

20. The display device according to claim 11, wherein the first bump and the second bump are insulated from each other by the protrusion.
